(19) United States
(12) Patent Application Publication
(10) Pub. No.: US 2011/0205193 A1
(43) Pub. Date: Aug. 25, 2011

(54) Operational amplifier with decreased through current, and display panel driver and display device incorporating the same

(75) Inventors: Kouichi Nishimura, Kanagawa (JP); Atsushi Shimatani, Kanagawa (JP)

(73) Assignee: Renesas Electronics Corporation, Kawasaki (JP)

(21) Appl. No.: 12/929,840

(22) Filed: Feb. 18, 2011

(30) Foreign Application Priority Data
Feb. 19, 2010 (JP) 2010-034720

(51) Int. Cl. G09G 5/00; H03F 3/45; H03F 3/16

(52) U.S. Cl. 345/204; 330/253; 330/277

(57) ABSTRACT

An operational amplifier is provided with: a high-side output transistor connected between an output terminal and a positive power supply line; a low-side output transistor connected between the output terminal and a negative power supply line; a first capacitor element connected between a first node and the output terminal; a second capacitor element connected between a second node and the output terminal; a first PMOS transistor having a source connected to the gate of the high-side output transistor and a drain connected to the gate of the low-side output transistor; a first NMOS transistor having a source connected to the gate of the low-side output transistor and a drain connected to the gate of the high-side output transistor; a second PMOS transistor having a source connected to the first node and a drain connected to the gate of the high-side output transistor; and a second NMOS transistor having a source connected to the second node and a drain connected to the gate of the low-side output transistor. The gates of the first and second PMOS transistors are commonly connected and fed with a first bias voltage, and the gates of the first and second NMOS transistors are commonly connected and fed with a second bias voltage.

### INCORPORATION BY REFERENCE

This application claims the benefit of priority based on Japanese Patent Application No. 2010-034720, filed on Feb. 19, 2010, the disclosure of which is incorporated herein by reference.

### BACKGROUND OF THE INVENTION

1. Field of the Invention

The present invention relates to an operational amplifier, and a display panel driver and display device incorporating the same, and in particular, to an output stage configuration of the operational amplifier.

2. Description of the Related Art

An operational amplifier is a basic building block in analog signal processing. Although conventional operational amplifiers were based on bipolar transistors, recent operational amplifiers are based on MOS transistors. Operational amplifiers comprised of MOS transistors are necessary, especially in an integrated circuit in which CMOS logic circuits and analog circuits are monolithically integrated. Further, to meet a demand for low voltage operation, a rail-to-rail operation is an indispensable requirement of the MOS operational amplifier. Hereinafter, examples of configuration and operations of the MOS operational amplifier that performs the rail-to-rail operation will be described.

FIG. 1 is a circuit diagram showing the operational amplifier configuration, in particular, the output stage configuration, which is disclosed in Japanese Patent Application Publication No. S61-35004. An operational amplifier 101 shown in FIG. 1 is provided with an amplifier 102 and an output stage 103. The output stage 103 includes PMOS transistors MP5, MP6, NMOS transistors MN5, MN6, bias voltage sources 104, 105 and constant current sources I3 and I4. The amplifier 102 has an input connected to an input terminal Vin and an output connected to the gate of the NMOS transistor MN6. The amplifier 102 operates as an input stage of the operational amplifier 101. The PMOS transistor MP6 has a source connected to a positive power supply line V_{DD} and a drain connected to an output terminal Vout. The NMOS transistor MN6 has a source connected to a negative power supply line (ground line) V_{SS} and a drain connected to the output terminal Vout.

The NMOS transistor MN5 has a source connected to the gate of the NMOS transistor MN6 and a drain connected to the gate of the PMOS transistor MP6. The PMOS transistor MP5 has a source connected to the gate of the PMOS transistor MP6 and a drain connected to the gate of the NMOS transistor MN6. The bias voltage source 104 is connected between the gate of the PMOS transistor MP5 and the positive power supply line V_{DD}, and the bias voltage source 105 is connected between the gate of the NMOS transistor MN5 and the negative power supply line V_{SS}. The bias voltage source 104 biases the gate of the PMOS transistor MP5 to a voltage level that is lower than the positive power potential V_{DD} by a voltage V_{BP1}. Meanwhile, the bias voltage source 105 biases the gate of the NMOS transistor MN5 to a voltage level that is higher than to the negative power potential V_{SS} by a voltage V_{BN1}. The PMOS transistor MP5 and NMOS transistor MN5 thus biased operate as a floating current source. The constant current source 13 is connected between the positive power supply line V_{DD} and the source of the NMOS transistor MP5. The constant current source 14 is connected between the negative power supply line V_{SS} and the source of the NMOS transistor MN5.

The NMOS transistor MN6 and the PMOS transistor MP6 in the output stage 103 perform a class AB operation. The idling current for achieving the class AB operation depends on the operations of the bias voltage sources 104, 105 and the PMOS transistor MP5 and the NMOS transistor MN5, which operate as the floating current source. The bias voltage sources 104, 105 and the floating current source are designed as follows: First, the voltage V_{BP1} of the bias voltage source 104 connected between the positive power supply line V_{DD} and the gate of the PMOS transistor MP5 is selected so as to be equal to the sum of gate-source voltages of the PMOS transistors MP6 and MP5, that is, so as to satisfy a following equation (1).

V_{BP1}=V_{GS(MP6)}+V_{GS(MP5)}. (1)

It should be noted that the gate-source voltage V_{GS} of a MOS transistor is generally represented by the following equation:

$${V}_{GS} = \sqrt{\frac{2 {I}_{D}}{β}} + {V}_{T} , \qquad ( 2 )$$

wherein the parameter β in equation (2) is defined by the following equation:

$$β = \frac{W}{L} μ {C}_{0} ,$$

where W is the gate width; L is the gate length; μ is the mobility; C_{O} is the gate dielectric film capacity per unit area; V_{T} is the threshold voltage; and I_{D} is the drain current.

The above-mentioned floating current source is basically designed so that the drain current of the PMOS transistor MP5 is equal to that of the NMOS transistor MN5. That is, the floating current source is designed so that a half of the current value I₃ from the constant current source I3 (I₃/2) is fed to each of the PMOS transistor MP5 and the NMOS transistor MN5. For the above-mentioned idling current I_{idle} (that is, the drain currents of the PMOS transistor MP6 and the NMOS transistor MN6), the following equation holds from equation (1):

$${V}_{BP 1} = \sqrt{\frac{{I}_{3}}{{β}_{( MP 6 )}}} + \sqrt{\frac{2 {I}_{idle}}{{β}_{( MP 5 )}}} + 2 {V}_{T} , \qquad ( 3 )$$

where β_{(MP6)} and β_{(MP5)} are values of the parameters β obtained with respect to the PMOS transistors MP6 and MP5, respectively, and V_{T} is the threshold voltage of the PMOS transistors MP6 and MP5. Although details of the circuit configuration of the bias voltage source 104 are not shown, the equation (3) can be solved for the idling current I_{idle} (it should be noted that the equation giving the idling current I_{idle} is not presented here, because the equation is so complicated).

The current level of the constant current source I4 needs to be equal to that of the constant current source I3. If these current levels are different from each other, a difference current therebetween flows to the output terminal of the amplifier 102, and when the output terminal of the amplifier 102 is an output terminal of an active load, the difference current leads to an increase in the offset voltage. The bias voltage source 105 connected between the negative power supply line V_{SS} and the gate of the NMOS transistor MN5 can be designed in the same manner.

The bias voltage sources 104 and 105 can be stabilized against the variations in the element properties, by configuring each of the bias voltage sources 104 and 105 with two MOS transistors and a constant current source. This is because the left side of equation (3), which defines the voltage V_{BP1}, depends on “2V_{T}” as in the right side of equation (3), and the term “2V_{T}” is cancelled in the both sides (no specific circuit example is not given here). As thus described, the circuit shown in FIG. 1 achieves the class AB operation by controlling the idling current I_{idle}.

In an operational amplifier, a phase compensation capacitor may be connected between the output terminal and the gate of the output MOS transistor (the PMOS transistor MP6 and the NMOS transistor MN6 in FIG. 1). An operational amplifier with such a configuration is disclosed, for example, in Japanese Patent Application Publication No. 2005-124120A. FIG. 2 is a circuit diagram showing the configuration of the operational amplifier 101A disclosed in Japanese Patent Application Publication No. 2005-124120A. As in FIG. 1, the operational amplifier 101A includes an output stage 103A that achieves the class AB operation. It should be noted that, in the operational amplifier 101A in FIG. 2, an input stage 102A is configured to have a differential input and a differential output. The output stage 103A includes phase compensation capacitors C1 and C2.

In detail, the input stage 102A includes PMOS transistors MP1 to MP4, NMOS transistors MN1 to MN4 and constant current sources I1 and I2. The NMOS transistors MN1 and MN2 form an NMOS differential pair. The gate of the NMOS transistor MN1 is connected to an inverting input terminal In⁻ and the gate of the NMOS transistor MN2 is connected to a non-inverting input terminal In⁺. The PMOS transistors MP1 and MP2 constitute a current mirror used as an active load. Specifically, the PMOS transistor MP1 has a source connected to the positive power supply line V_{DD} and has a drain and gate commonly connected to the drain of the NMOS transistor MN1. The PMOS transistor MP2 has a source connected to the positive power supply line V_{DD}, a drain connected to the drain of the NMOS transistor MN2 and a gate connected to the gate of the PMOS transistor MP1.

The PMOS transistors MP3 and MP4 constitute a PMOS differential pair. The gate of the PMOS transistor MP3 is connected to the inverting input terminal In⁻ and the gate of the PMOS transistor MP4 is connected to the non-inverting input terminal In⁺. The NMOS transistors MN3 and MN4 constitute a current mirror used as an active load. Specifically, the NMOS transistor MN3 has a source connected to the negative power supply line V_{SS} and has a drain and gate commonly connected to the drain of the PMOS transistor MP3. The NMOS transistor MN4 has a source connected to the negative power supply line V_{SS}, a drain connected to the drain of the PMOS transistor MP4 and a gate connected to the gate of the NMOS transistor MN3.

The constant current source I1 is connected between the commonly-connected sources of the NMOS transistors MN1, MN2 and the negative power supply line V_{SS}. Similarly, the constant current source I2 is connected between the commonly-connected sources of the PMOS transistors MP3, MP4 and the positive power supply line V_{DD}.

The input stage 102A thus configured outputs two single-end output signals corresponding to the differential input signals inputted to the inverting input terminal In⁻ and the non-inverting input terminal In⁺ from the drain of the PMOS transistor MP2 and the drain of the NMOS transistor MN4, respectively.

The configuration of the output stage 103A is substantially similar to that of the output stage 103 of the operational amplifier 101 in FIG. 1. However, the drain of the PMOS transistor MP2 is connected to one terminal of the floating current source formed of the PMOS transistor MP5 and the NMOS transistor MN5, and the drain of the NMOS transistor MN4 is connected to the other terminal of the floating current source. The phase compensation capacitor C1 is connected between the gate of the PMOS transistor MP6 and the output terminal Vout, and the phase compensation capacitor C2 is connected between the gate of the NMOS transistor MN6 and the output terminal Vout.

Schematically, the operational amplifier 101A in FIG. 2 operates as follows: The output signal of the NMOS differential pair is converted into a single-end output signal by the PMOS transistors MP1 and MP2 that constitute the active load and the resultant single-end output signal is outputted to the output stage 103A. That is, the commonly-connected drains of the PMOS transistor MP2 and the NMOS transistor MN2 are used as a single-end output terminal. The resultant single-end output is inputted to the gate of the PMOS transistor MP6.

Similarly, the output signal of the NMOS differential pair is converted into a single-end output signal by the NMOS transistors MN3 and MN4 constituting the active load and the resultant single-end output signal is outputted to the output stage 103A. That is, the commonly-connected drains of the NMOS transistor MN4 and the PMOS transistor MP4 are used as a single-end output terminal. The resultant single-end output signal is inputted to the gate of the NMOS transistor MN6. In this manner, the output signals of the NMOS differential pair and the PMOS differential pair are added together.

Although FIG. 2 shows that the phase compensation capacitors C1 and C2 are inserted into the operational amplifier 101A, a resistor or the like (not shown) may be inserted in series with the phase compensation capacitors C1 and C2 in general MOS amplifiers, to thereby eliminate the zero point of the phase delay.

Japanese Patent Application Publication No. 2006-94533 and the corresponding U.S. Application Publication No. 2006/0066400 A1 also disclose an operational amplifier with such a configuration in which the output stage achieves a class AB operation and includes phase compensation capacitors.

FIG. 3 is a circuit diagram showing the configuration of an operational amplifier 101B as an improvement of the operational amplifier 101A shown in FIG. 2; the configuration shown in FIG. 3 is disclosed in Japanese Patent Application Publication No. 2006-295365 and the corresponding U.S. Pat. No. 7,405,622. The operational amplifier 101B shown in FIG. 3 is different from the operational amplifier 101A in FIG. 2 in that the constant current sources I3 and I4 in FIG. 2 are removed and a floating current source I5 is inserted between the drains of the PMOS transistor MP1 and the NMOS transistor MN3 in the input stage 102B. Other structures of the operational amplifier 101B shown in FIG. 3 are same as those in FIG. 2.

One important requirement in the operation of the operational amplifier 101A in FIG. 2 is matching between the constant current sources I3 and I4. The operational amplifier 101B in FIG. 3 is based on a technical concept that, in place of these constant current sources, a current mirror including the PMOS transistors MP1 and MP2 and a current mirror including the NMOS transistors MN3 and MN4, which act as active loads, are used. Advantageously, when the floating current source I5 is inserted between the input terminals of the current mirror including the PMOS transistors MP1, MP2 and the current mirror including the NMOS transistors MN3, MN4, the output terminal of the current mirror including the PMOS transistors MP1 and MP2 provides the same function as the constant current source I3 in FIG. 2, and the output terminal of the current mirror including the NMOS transistors MN3 and MN4 provides the same function as the constant current source I4 in FIG. 2. That is, a dual effect is obtained in which the active load also serves as the constant current source. By connecting the floating current source I5 between the input terminals of the current mirror including the PMOS transistors MP1, MP2 and the current mirror including the NMOS transistors MN3, MN4 in this manner, the input currents of the two current mirrors are controlled to be accurately equal to each other, resulting in that the output currents are equal to each other. As thus discussed, the use of the floating current source I5 advantageously eliminates the offset voltage.

The circuit configuration shown in FIG. 3 provides a rail-to-rail amplifier which operates in the entire of the input/output voltage range from the negative power supply voltage to the positive power supply voltage, while reducing the offset voltage. The circuit configuration shown in FIG. 3 also allows designing the constant current source I5 with a simple circuit configuration, as compared with the two current sources I3 and I4, which are required to have the same characteristics.

As described in Japanese Patent Application Publication No. S61-35004, the output stage 103B also provides a class AB operation, and therefore the detailed description thereof is omitted herein. In the operational amplifier 101B in FIG. 3, as is the case of the operational amplifier 101A in FIG. 2, the phase compensation capacitors C1 and C2 are inserted. A resistor or the like (not shown) may be inserted in series with each of the phase compensation capacitors C1 and C2 to eliminates the zero point of the phase delay, as is the case of generally-used MOS amplifiers.

Nevertheless, the operational amplifiers shown in FIGS. 2 and 3 suffer from a drawback that a through current may flow when the output terminal Vout is placed into the high impedance state, resulting in an undesired increase in the dynamic power consumption. For example, when an operational amplifier shown in any one of FIGS. 1 to 3 is used as an output amplifier integrated within a source driver of a liquid crystal display device, a through current flows through the operational amplifier during the charge recovery period in which the corresponding data line of the liquid crystal display panel, which functions as a capacity load, is separated from the output terminal of the operational amplifier. FIGS. 4A and 4B show output properties in a case where the operational amplifier shown in FIG. 2 or FIG. 3 is used as an output amplifier for a source driver, wherein FIG. 4A shows the output voltage waveform and FIG. 4B shows the output current waveforms. As understood from the output current waveforms shown in FIG. 4B, the current waveform of the output PMOS transistor MP6 partially matches that of the output NMOS transistor MN6. This part indicates the through current as a useless current component, not indicating the effective output load current. As a result, a problem of an increased dynamic power consumption is caused. It should be noted that, in FIG. 4B, these current waveforms match each other and are shown as one line. In fact, the current waveforms of the output PMOS transistor MP6 and the output NMOS transistor MN6 overlap each other.

### SUMMARY

The inventor has discovered that the generation of the through current in a case where the output terminal is placed into the high-impedance state results from the fact that variations in the voltage level of the output terminal causes variations in the voltage levels of the gates of the output transistors through the phase compensation capacitors. The present invention effectively addresses such problem.

In an aspect of the present invention, an operational amplifier is provided with: a high-side output transistor connected between an output terminal and a positive power supply line; a low-side output transistor connected between the output terminal and a negative power supply line; a first capacitor element connected between a first node and the output terminal; a second capacitor element connected between a second node and the output terminal; a first PMOS transistor having a source connected to the gate of the high-side output transistor and a drain connected to the gate of the low-side output transistor; a first NMOS transistor having a source connected to the gate of the low-side output transistor and a drain connected to the gate of the high-side output transistor; a second PMOS transistor having a source connected to the first node and a drain connected to the gate of the high-side output transistor; and a second NMOS transistor having a source connected to the second node and a drain connected to the gate of the low-side output transistor. The gates of the first and second PMOS transistors are commonly connected and fed with a first bias voltage, and the gates of the first and second NMOS transistors are commonly connected and fed with a second bias voltage.

In the operational amplifier thus constructed, the second PMOS transistor and the second NMOS transistor electrically separate the gates of the high-side and low-side output transistors from the output terminal. Therefore, the configuration of the operational amplifier effectively avoid the generation of a through-current resulting from variations in the voltage levels of the gates of the output transistors caused by variations in the voltage level of the output terminal through the phase compensation capacitors.

The operational amplifier thus configured is preferably used in a display panel driver which drives a display panel, especially in a source driver which drives data lines of a liquid crystal display panel of a liquid crystal display device.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a circuit diagram showing an example of the configuration of a conventional operational amplifier;

FIG. 2 is a circuit diagram showing another example of the configuration of the conventional operational amplifier;

FIG. 3 is a circuit diagram showing still another example of the configuration of the conventional operational amplifier;

FIG. 4A is a graph showing an exemplary output voltage waveform of the conventional operational amplifier;

FIG. 4B is a graph showing exemplary output current waveforms of the conventional operational amplifier;

FIG. 5A is a circuit diagram showing an exemplary configuration of an operational amplifier of a first embodiment of the present invention;

FIG. 5B is a circuit diagram showing another exemplary configuration of the operational amplifier of the first embodiment;

FIG. 6 is a circuit diagram showing an exemplary configuration of an operational amplifier of a second embodiment of the present invention;

FIG. 7 is a circuit diagram showing an exemplary configuration of an operational amplifier of a third embodiment of the present invention;

FIG. 8A is a graph showing an exemplary output voltage waveform of the operational amplifier shown in FIG. 7;

FIG. 8B is a graph showing an exemplary an output current waveforms of the operational amplifier shown in FIG. 7;

FIG. 9 is a circuit diagram showing an exemplary configuration of an operational amplifier of a fourth embodiment of the present invention;

FIG. 10A is a schematic diagram showing an exemplary configuration of a liquid crystal display device provided with the operational amplifier of the first embodiment; and

FIG. 10B is a schematic diagram showing an exemplary configuration of a liquid crystal display device provided with the operational amplifier of any of the second to fourth embodiments.

### DESCRIPTION OF PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

### First Embodiment

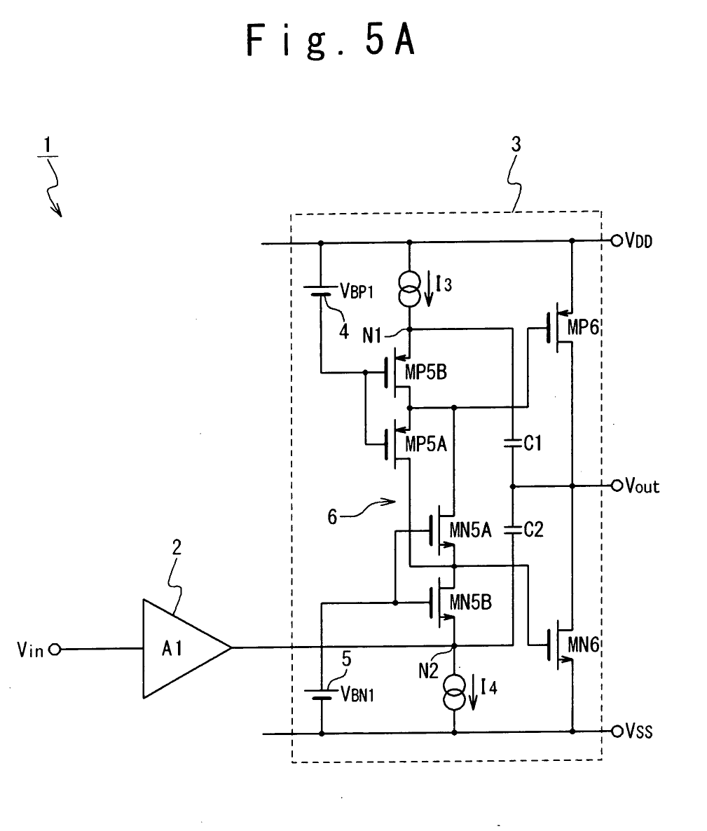

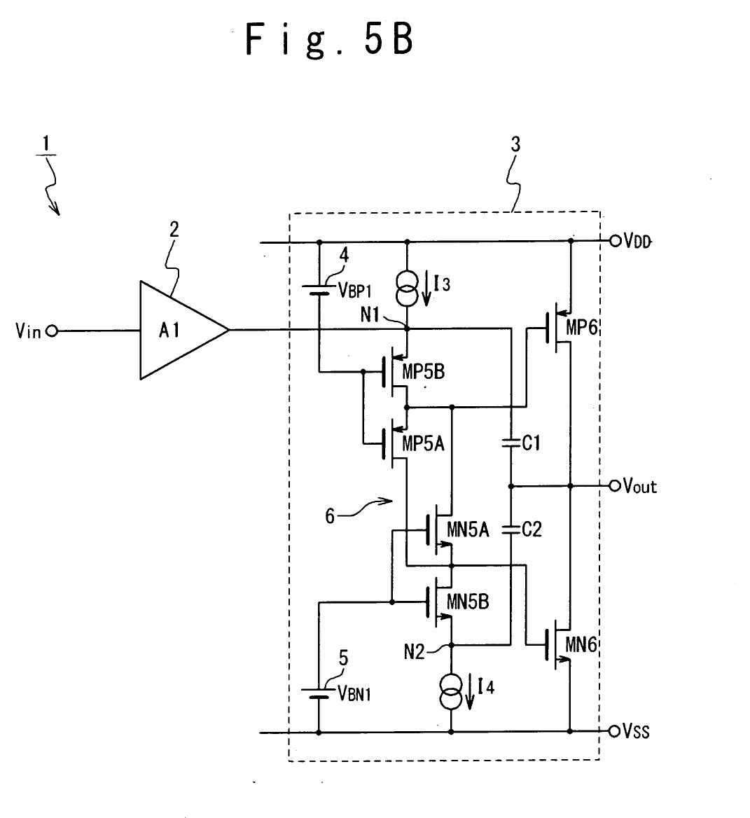

FIG. 5A is a circuit diagram showing an exemplary configuration of an operational amplifier 1 of a first embodiment of the present invention, in particular, showing an exemplary configuration of an output stage of the operational amplifier 1. In this embodiment, the operational amplifier 1 includes an amplifier 2 that operates as an input stage; and an output stage 3. The amplifier 2 has an input connected to the input terminal Vin and an output connected to the output stage 3.

The output stage 3 includes PMOS transistors MP5A, MP5B, MP6, NMOS transistors MN5A, MN5B, MN6, bias voltage sources 4, 5, constant current sources I3, I4 and phase compensation capacitors C1, C2. The PMOS transistor MP6 has a source connected to the positive power supply line V_{DD} and a drain connected to an output terminal Vout. The NMOS transistor MN6 has a source connected to the negative power supply line V_{SS} and a drain connected to the output terminal Vout. The PMOS transistor MP6 is a high-side output transistor for pulling up the output terminal Vout and the NMOS transistor MN6 is a low-side output transistor for pulling down the output terminal Vout.

The PMOS transistor MP5A and the NMOS transistor MN5A operate as a floating current source 6 connected between the gates of the PMOS transistor MP6 and the NMOS transistor MN6. The PMOS transistor MP5A has a source connected to the gate of the PMOS transistor MP6 and a drain connected to the gate of the NMOS transistor MN6. The NMOS transistor MN5A, on the other hand, has a source connected to the gate of the NMOS transistor MN6 and a drain connected to the gate of the PMOS transistor MP6.

The constant current source I3 is connected between the positive power supply line V_{DD} and a node N1, and the PMOS transistor MP5B is connected between the node N1 and the floating current source 6. The constant current source I3 supplies a constant bias current to the node N1. The phase compensation capacitor C1 is connected between the node N1 and the output terminal Vout. The PMOS transistor MP5B has a source connected to the node N1 and a drain connected to one terminal of the floating current source 6, that is, the gate of the PMOS transistor MP6. The gate of the PMOS transistor MP5B is commonly connected to the gate of the PMOS transistor MP5A.

It should be noted that the phase compensation capacitor C1 is connected to the gate of the PMOS transistor MP6, which operations as the high-side output transistor, through the PMOS transistor MP5B. As is discussed later, it is important that the phase compensation capacitor C1 is not directly connected to the gate of the PMOS transistor MP6.

Similarly, the constant current source I4 is connected between the negative power supply line V_{SS} and a node N2, and the NMOS transistor MN5B is connected between the node N2 and the floating current source 6. The constant current source I4 draws a constant bias current from the node N2. The phase compensation capacitor C2 is connected between the node N2 and the output terminal Vout. The NMOS transistor MN5B has a source connected to the node N2 and a drain connected to one end of the floating current source 6, that is, the gate of the NMOS transistor MN6. The gate of the NMOS transistor MN5B is commonly connected to the gate of the NMOS transistor MN5A. As is the case of the phase compensation capacitor C1, it is important that the phase compensation capacitor C2 is not directly connected to the gate of the NMOS transistor MN6. The output of the amplifier 2 is connected to the node N2.

The bias voltage source 4 is connected between the gates of the PMOS transistors MP5A, MP5B and the positive power supply line V_{DD} to bias the gate of the PMOS transistor MP5A, MP5B to a voltage level that is lower than the positive power potential V_{DD} by the voltage V_{BP1}. The voltage V_{BP1} of the bias voltage source 4 is adjusted so that the PMOS transistor MP5B operates in the triode region.

Similarly, the bias voltage source 5 is connected between the gates of the NMOS transistors MN5A, MN5B and the negative power supply line V_{SS} to bias the gate of the NMOS transistors MN5A, MN5B to a voltage level that is higher than the negative power potential V_{SS} by the voltage V_{BN1}. The voltage V_{BN1} of the bias voltage source 4 is adjusted so that the NMOS transistor MN5B operates in the triode region.

The operational amplifier 1 in FIG. 5A operates as follows: In this embodiment, the operations of the cascade-connected two PMOS transistors MP5A, MP5B and two NMOS transistor MN5A, MN5B are important. In the operational amplifier 1 in FIG. 5A, the PMOS transistor MP5B and the NMOS transistor MN5B operate in the triode region, and the PMOS transistor MP5A and the NMOS transistor MN5A operate in the pentode region.

When a certain MOS transistor operates in the triode region, it usually means that the MOS transistor operates as a resistor. In this embodiment, however, the PMOS transistor MP5B and the NMOS transistor MN5B operate not only as resistors, but also are turned off as necessary, thereby electrically separating the gates of the PMOS transistor MP6 and the NMOS transistor MN6, which operate as the output transistors, from the output terminal Vout. For the node N1, for example, the PMOS transistor MP5B is turned off when the voltage level V_{(N1)} of the node N1 is decreased by the phase compensation capacitor C1 so as to satisfy the following equation (4):

V_{(N1)}<V_{DD}−V_{BP1}+|V_{T(MP5B)}|, (4)

where |V_{T(MP5B)}| is the absolute value of the threshold voltage of the PMOS transistor MP5B. It should be noted that the equation (4) holds on the basis of the fact that the gates of the PMOS transistors MP5A and MP5B are commonly connected to the bias power supply line 4. Similarly, for the node N2, the NMOS transistor MN5B is turned off when the voltage level V_{(N2)} of the node N2 is increased by the phase compensation capacitor C2. The gates of the PMOS transistor MP6 and the NMOS transistor MN6 are electrically separated from the output terminal Vout through such operation; even when the output terminal Vout rapidly varies, the variations does not affect the voltage levels of the gates of the output transistors. This effectively avoids a through current being generated through the PMOS transistor MP6 and the NMOS transistor MN6.

Operating the PMOS transistor MP5B and the NMOS transistor MN5B in the triode region is also advantageous for reducing the drain-source voltages V_{DS(MP5B)} and V_{DS(MN5B)} thereof. When the PMOS transistor MP5B and the NMOS transistor MN5B are operated in the triode region, the drain-source voltages V_{DS(MP5B)} and V_{DS(MN5B)} are set to the difference in gate-source voltages, that is, V_{GS(MP5B/MN5B)}−V_{GS(MP5A/MN5A)}. In other words, the source-drain voltages of the PMOS transistor MP5B, NMOS transistor MN5B are set to the value obtained by subtracting the gate-source voltage V_{GS} in the pentode region from the gate-source voltage V_{GS} in the triode region. More specifically, the drain-source voltage V_{DS(MP5B)} and V_{DS(MN5B)} are each set to a value in a range from several tens of millivolts to a hundred millivolts.

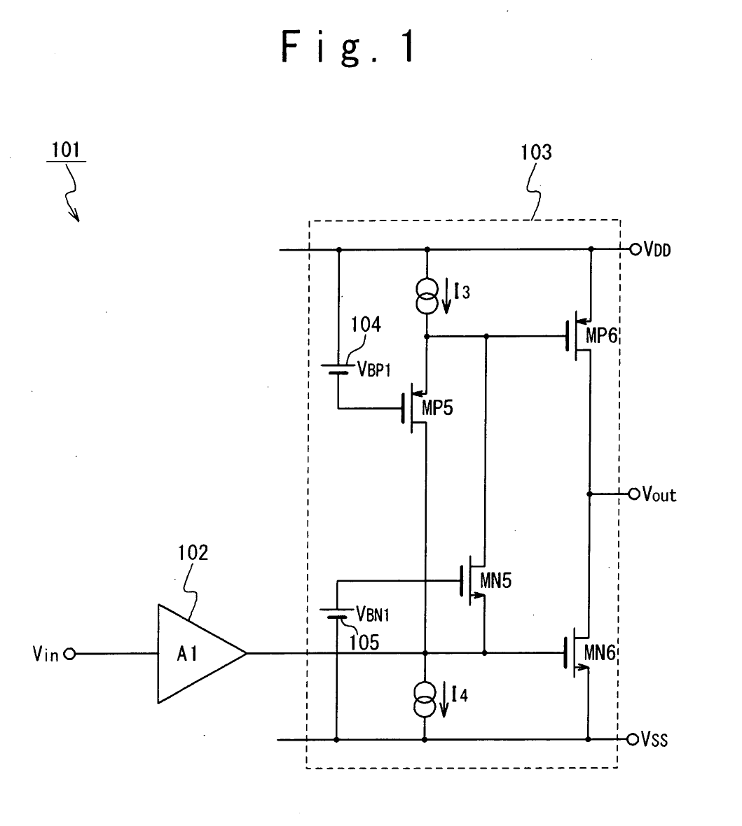

It should be noted that the output of the amplifier 2 may be connected to the node N1 (that is, the source of the PMOS transistor MP5B) as shown in FIG. 5B. In both cases of FIGS. 5A and 5B, the operational amplifier 1 operates basically in the same way. The description of the circuit shown in FIG. 5B is not given here, because basic operations other than the above-discussed operations are same as those of the operational amplifier in FIG. 1.

### Second Embodiment

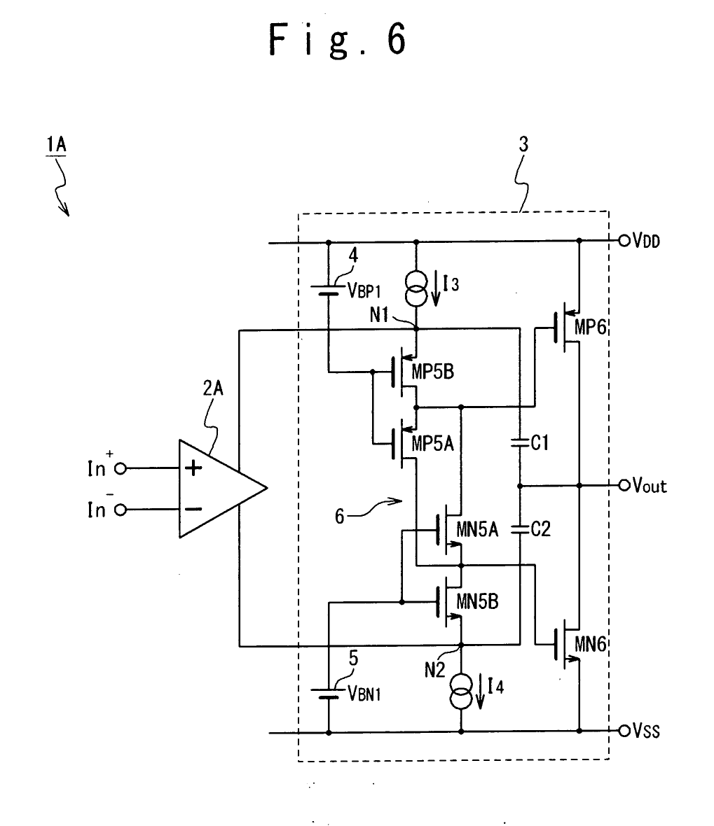

FIG. 6 is a circuit diagram showing an exemplary configuration of an operational amplifier 1A of a second embodiment of the present invention. In the second embodiment, the amplifier 2 shown in FIGS. 5A and 5B is replaced with a differential amplifier 2A having two outputs of the same phase, a non-inverting input and an inverting input. One of the two outputs of the differential amplifier 2A is connected to the source of the NMOS transistor MN5B and the other is connected to the source of the PMOS transistor MP5B. Other circuit structures of the operational amplifier 1A are same as those of the operational amplifier 1 in FIGS. 5A and 5B.

In the operational amplifier 1A in FIG. 6, the differential amplifier 2A, which functions as an input stage, symmetrically supplies a signal to the PMOS transistors and the NMOS transistors in the output stage 3. This effectively improves the symmetric property of the waveform outputted from the output terminal Vout. Further, the use of the differential amplifier 2A as the input stage allows using the operational amplifier 1A of this embodiment in the same way as a commonly-used operational amplifier having non-inverting and inverting inputs as a whole. Details of the operational amplifier 1A are not described here, since basic operations thereof are same as those of the operational amplifier 1 of the first embodiment.

### Third Embodiment

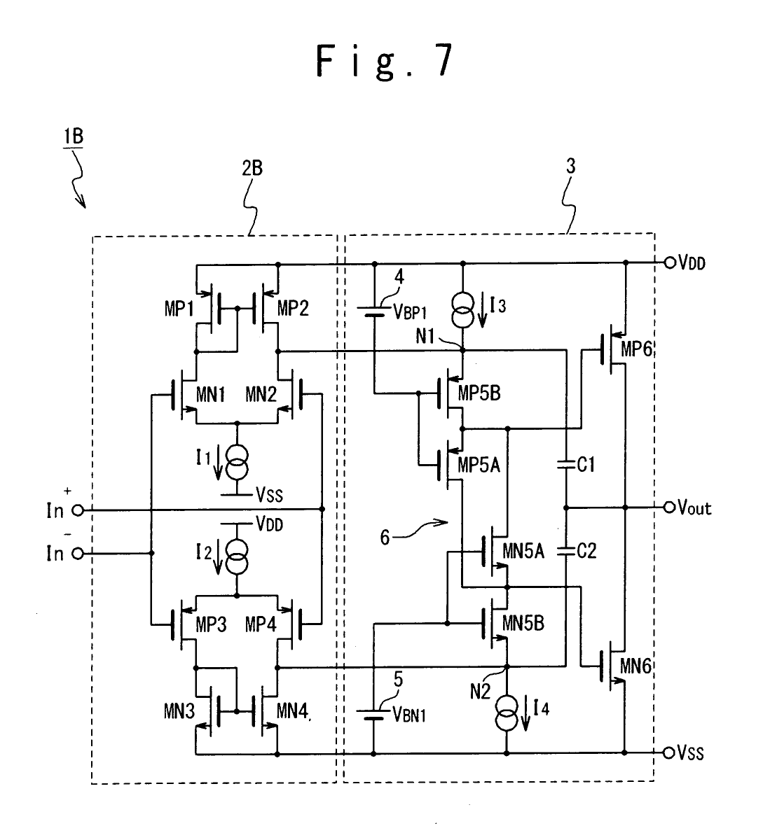

FIG. 7 is a circuit diagram showing an exemplary configuration of an operational amplifier 1B of a third embodiment of the present invention. In the third embodiment, an input stage 2B incorporating both of an NMOS differential pair and a PMOS differential pair is used. The configuration of the output stage 3 of this embodiment is same as that of the second embodiment. Hereinafter, a detailed description is given of the operational amplifier 1B of this embodiment.

In the third embodiment, the input stage 2B includes PMOS transistors MP1 to MP4, NMOS transistors MN1 to MN4 and constant current sources I1 and I2. The NMOS transistors MN1 and MN2 constitute an NMOS differential pair; the gate of the NMOS transistor MN1 is connected to the inverting input terminal In⁻ and the gate of the NMOS transistor MN2 is connected to the non-inverting input terminal In⁺. The PMOS transistors MP1 and MP2 constitute a current mirror used as an active load. Specifically, the PMOS transistor MP1 has a source connected to the positive power supply line V_{DD} and a drain and gate commonly connected to the drain of the NMOS transistor MN1. The PMOS transistor MP2 has a source connected to the positive power supply line V_{DD}, a drain connected to the drain of the NMOS transistor MN2 and a gate commonly connected to the gate of the PMOS transistor MP1.

The PMOS transistors MP3 and MP4 constitute a PMOS differential pair; the gate of the PMOS transistor MP3 is connected to the inverting input terminal In⁻ and the gate of the PMOS transistor MP4 is connected to the non-inverting input terminal In⁺. The NMOS transistor MN3 and MN4 constitute a current mirror used as an active load. Specifically, the NMOS transistor MN3 has a source connected to the negative power supply line V_{SS}, and a drain and gate commonly connected to the drain of the PMOS transistor MP3. The NMOS transistor MN4 has a source connected to the negative power supply line V_{SS}, a drain connected to the drain of the PMOS transistor MP4 and a gate commonly connected to the gate of the NMOS transistor MN3.

The constant current source I1 is connected between the commonly-connected sources of the NMOS transistors MN1, MN2 and the negative power supply line V_{SS} to draw a constant bias current from the commonly-connected sources of the NMOS transistors MN1 and MN2. Similarly, the constant current source I2 is connected between the commonly-connected sources of the PMOS transistors MP3, MP4 and the positive power supply line V_{DD}, to supply a constant bias current to the commonly-connected sources of the PMOS transistors MP3 and MP4.

The input stage 2B thus configured outputs two single-end output signals corresponding to the differential input signals inputted to the inverting input terminal In⁻ and the non-inverting input terminal In⁺ from the drains of the PMOS transistor MP2 and the NMOS transistor MN4. The drain of the PMOS transistor MP2 is connected to the node N1 (that is, the source of the PMOS transistor MP5B), and the drain of the NMOS transistor MN4 is connected to the node N2 (that is, the source of the NMOS transistor MN5B).

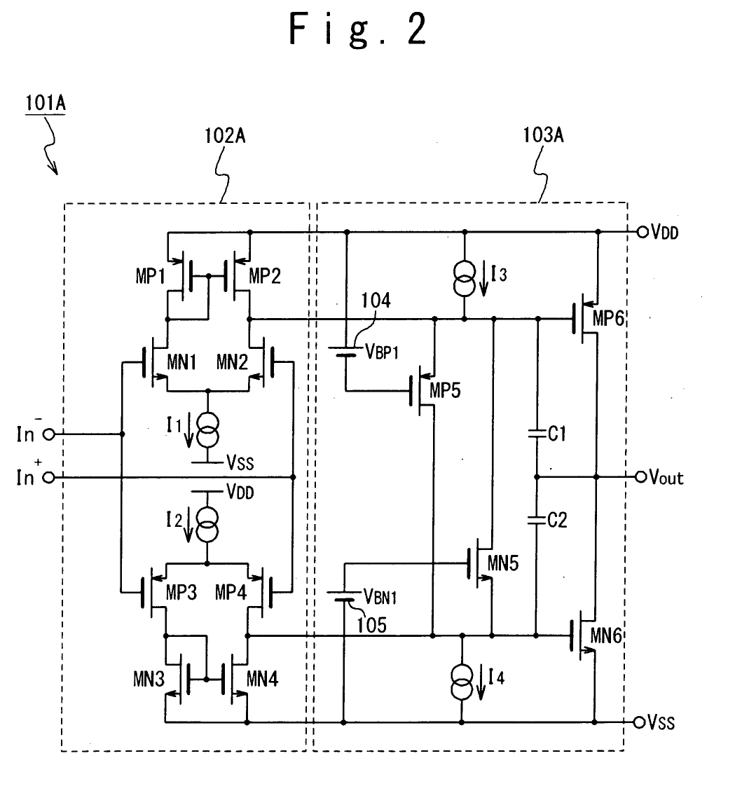

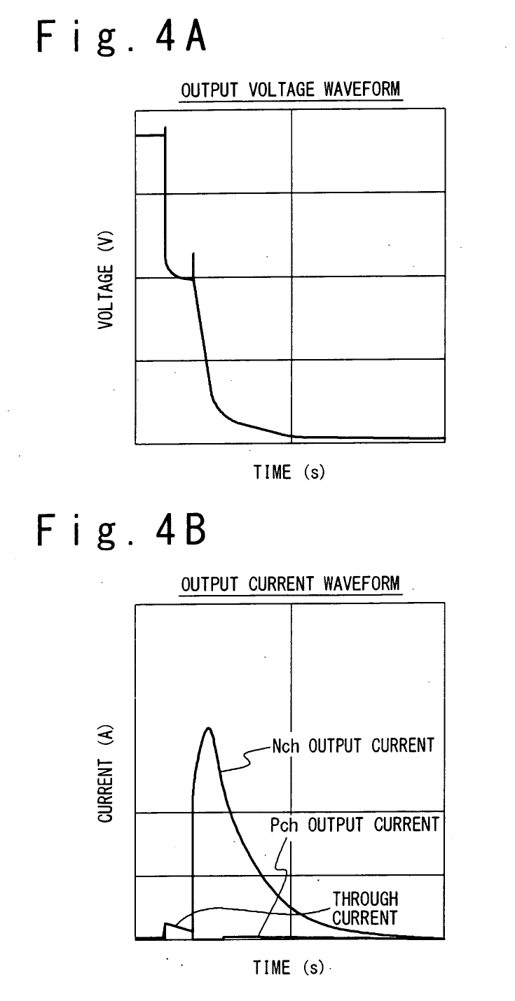

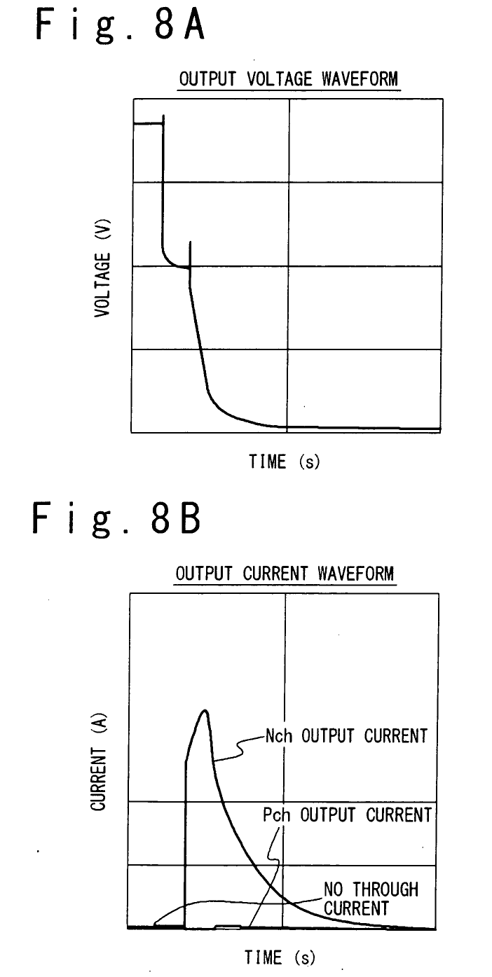

The operation of the input stage 2B shown in the operational amplifier 1B in FIG. 7 are same as that of the operational amplifier 101A shown in FIG. 2 and the operation of the output stage 3 is as described above with reference to FIG. 5A. In the following, a difference between this operational amplifier 1B and the conventional operational amplifier is described on the basis of a simulation result of the operational amplifier 1B in FIG. 7. FIGS. 8A and 8B are graphs showing the simulation results of the operational amplifier 1B in FIG. 7. One would understand the advantage of the operational amplifier 1B shown in FIG. 7 by comparing FIGS. 4A and 4B, which are graphs showing the simulation results of the conventional operational amplifier, with FIGS. 8A and 8B, which are the graphs showing the simulation results of the operational amplifier 1B shown in FIG. 7. As shown in FIG. 8B, there is no period during which currents flows through the NMOS transistor MN6 and the PMOS transistor MP6 at the same time. This implies that the circuit configuration shown in FIG. 7 effectively addresses the problem of the through current occurred in the conventional operational amplifier. As described above, this results from the fact that the phase compensation capacitors C1 and C2 are not directly connected to the gates of NMOS transistor MN6 and the PMOS transistor MP6, which operates as the output transistors. In other words, the circuit configuration of the operational amplifier 1B shown in FIG. 7 effectively avoid undesired changes in the voltage levels of the gates of the output transistors through the phase compensation capacitors C1 and C2.

### Fourth Embodiment

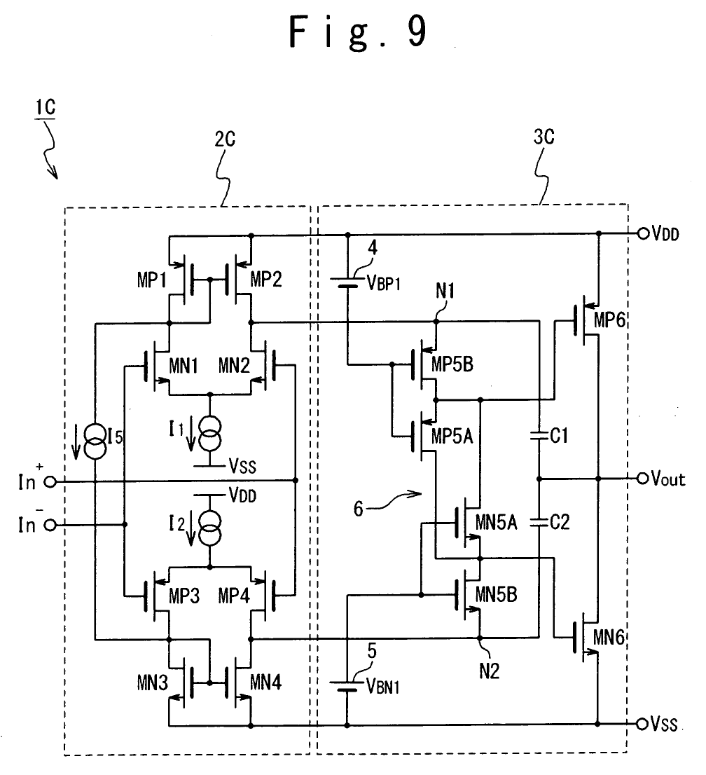

FIG. 9 is a circuit diagram showing an exemplary configuration of an operational amplifier 1C of a fourth embodiment of the present invention. In the fourth embodiment, the constant current sources I3 and I4 of the output stage 3 in the operational amplifier 1B in FIG. 7 are replace with a floating current source 15 inserted between the drains of the PMOS transistor MP1 and the NMOS transistor MN3. The output stage without the constant current sources I3 and I4 is denoted by the reference numeral 3C. Other circuit configurations of the operational amplifier 1C shown in FIG. 9 are same as those in the operational amplifier 1B in FIG. 7.

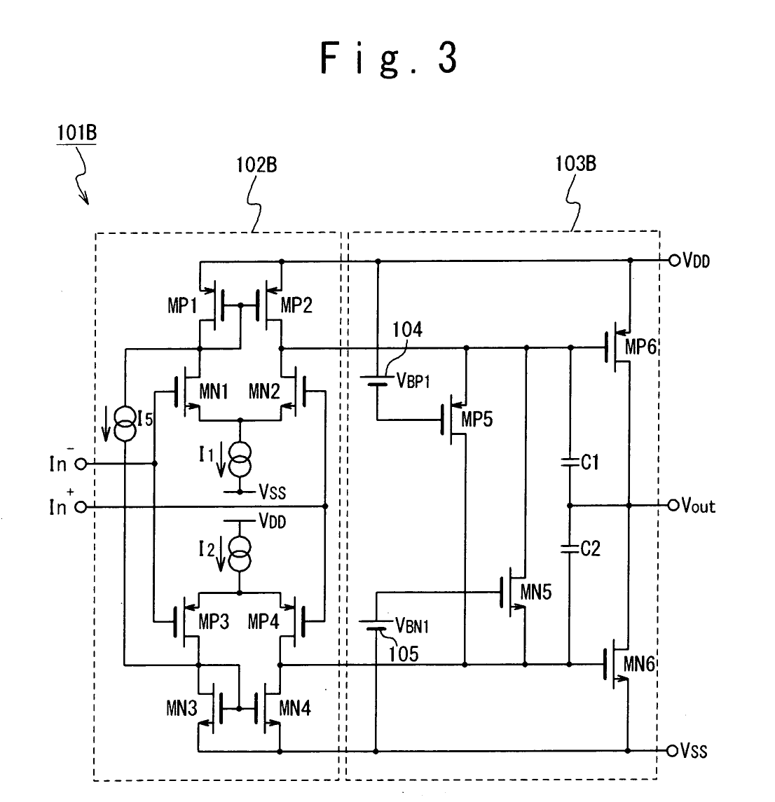

The function of the floating current source 15 is same as that shown in the operational amplifier 101B in FIG. 3; when the floating current source 15 is introduced, the output terminal of the current mirror including the PMOS transistors MP1 and MP2 functions in the same way as the constant current source I3 in FIG. 7, and the output terminal of the current mirror including the NMOS transistors MN3 and MN4 functions in the same way as the constant current source I4 in FIG. 7. Thus, the input currents of the two current mirrors are controlled to be accurately equal to each other, resulting in that the output currents thereof are also equal to each other. As described above, the use of the floating current source 15 advantageously eliminates the offset voltage.

The above-mentioned operational amplifiers 1A to 1C are each suitable as output amplifiers integrated within a source driver which drives data lines of the LCD (liquid crystal display) panel in the liquid crystal display device, especially in a case where they are used as so-called rail-to-rail operational amplifiers that does not include offset cancel circuits.

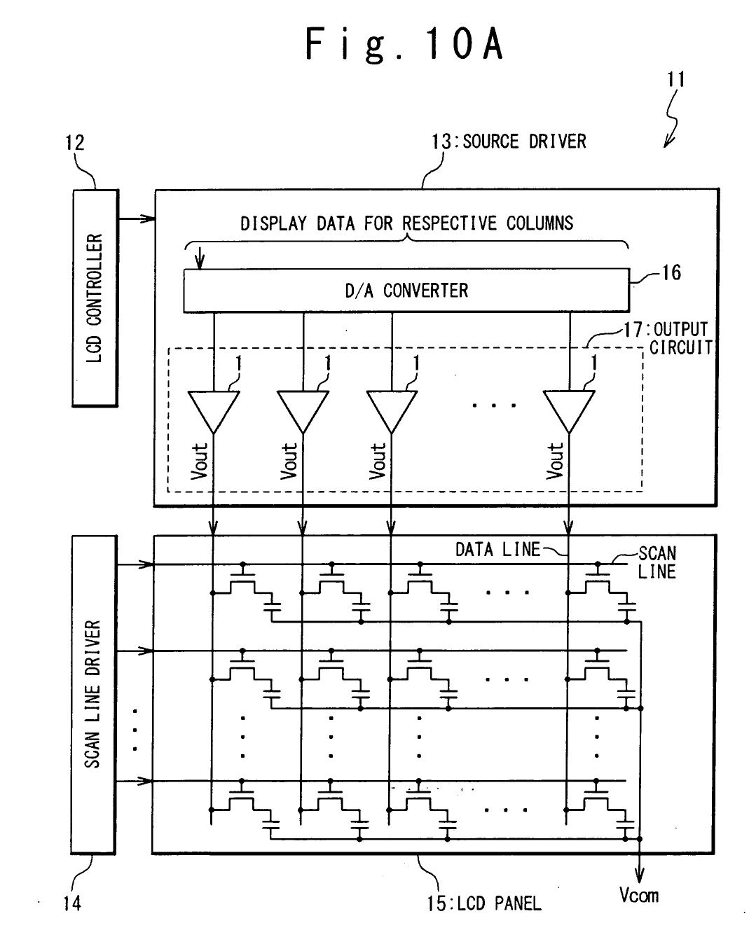

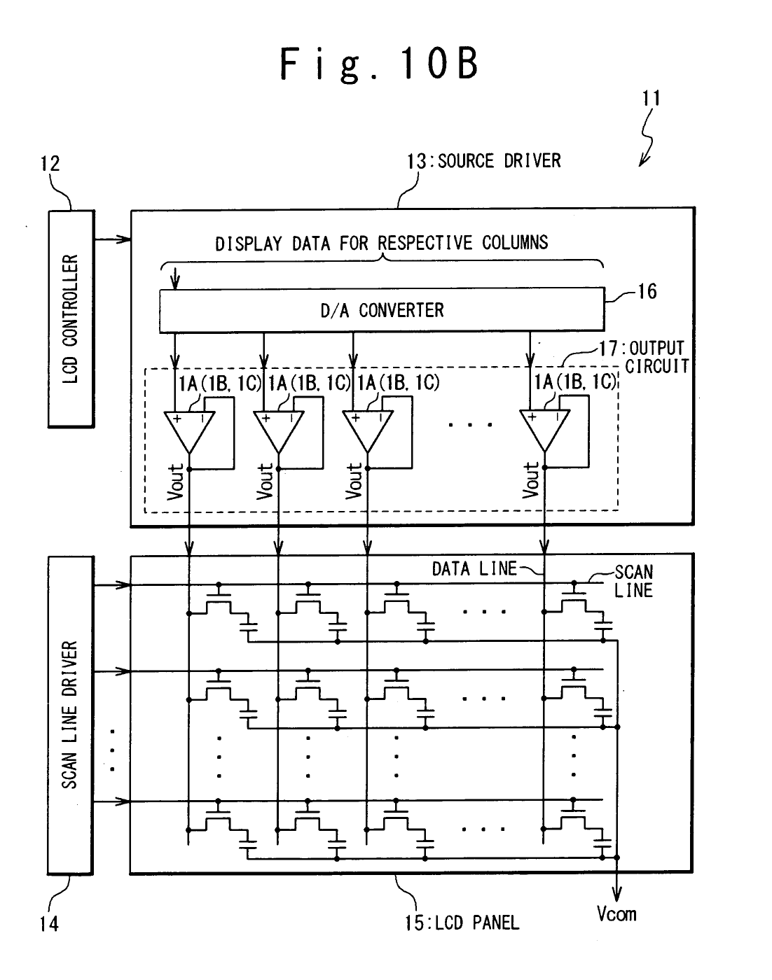

FIG. 10A is a block diagram schematically showing an exemplary configuration of a liquid crystal display device 11 incorporating the operational amplifiers 1 in the source driver. The liquid crystal display device 11 includes an LCD controller 12, a source driver 13, a scan line driver 14 and an LCD panel 15. The LCD controller 12 supplies display data specifying the gray-levels of the respective pixels of the LCD panel 15 to the source driver 13. The source driver 13 drives the data lines (signal lines) of the LCD panel 15 in response to the display data. The scan line driver 14 drives the scan lines of the LCD panel 15. The LCD panel 15 incorporates pixels at respective intersections of data lines and scan lines to display an image corresponding to the display data.

The source driver 13 includes a D/A conversion circuit 16 and an output circuit 17. The D/A conversion circuit 16 outputs gray-levels voltages corresponding to the display data. The output circuit 17 incorporates the above-mentioned operational amplifiers 1. The operational amplifiers 1 respectively output drive voltages corresponding to the gray-level voltages received from the D/A conversion circuit 16 to the corresponding data lines. As a result, the respective pixels of the LCD panel 15 are driven.

FIG. 10B is a block diagram schematically showing an exemplary configuration of a liquid crystal display device 11A incorporating any of the operational amplifiers 1A, 1B and 1C within the source driver. The liquid crystal display device 11A in FIG. 10B has the same configuration as the liquid crystal display device 11 in FIG. 10A except that the output terminal of each operational amplifier (1A, 1B or 1C) is connected to one of the two input terminals (for example, the inverting input terminal).

It is apparent that the present invention is not limited to the above embodiments, but may be modified and changed without departing from the scope of the invention. For example, although the liquid crystal display devices incorporating the operational amplifiers 1, 1A to 1C within the source driver for driving the LCD panel are described above, it is apparent to those skilled in the art that the present invention may be applied to a display panel driver for driving data lines (signal lines) of other display panels that function as a capacity load.

What is claimed is:

1. An operational amplifier, comprising:
a high-side output transistor connected between an output terminal and a positive power supply line;
a low-side output transistor connected between said output terminal and a negative power supply line;
a first capacitor element connected between a first node and said output terminal;
a second capacitor element connected between a second node and said output terminal;
a first PMOS transistor having a source connected to a gate of said high-side output transistor and a drain connected to a gate of said low-side output transistor;
a first NMOS transistor having a source connected to the gate of said low-side output transistor and a drain connected to the gate of said high-side output transistor;
a second PMOS transistor having a source connected to said first node and a drain connected to the gate of said high-side output transistor; and
a second NMOS transistor having a source connected to said second node and a drain connected to the gate of said low-side output transistor,
wherein gates of said first and second PMOS transistors are commonly connected and fed with a first bias voltage, and
wherein gates of said first and second NMOS transistors are commonly connected and fed with a second bias voltage.

2. The operational amplifier according to claim 1, wherein said first and second bias voltages are adjusted so that said second PMOS transistor and said second NMOS transistor operate in a triode region.

3. The operational amplifier according to claim 1, further comprising: an amplifier having an output connected to the source of said second PMOS transistor or the source of said second NMOS transistor.

4. The operational amplifier according to claim 1, further comprising:
a differential amplifier having a non-inverting input, an inverting input, a first output connected to the source of said second PMOS transistor and a second output connected to the source of said second NMOS transistor.

5. The operational amplifier according to claim 1, further comprising:
a NMOS differential pair including third and fourth NMOS transistors having commonly-connected sources;
a first constant current source drawing a current from the sources of said third and fourth NMOS transistors;
a first current mirror connected to drains of said third and fourth NMOS transistors;
a PMOS differential pair including third and fourth PMOS transistors having commonly-connected sources;
a second constant current source supplying a current to sources of said third and fourth PMOS transistors;
a second current mirror connected to drains of said third and fourth PMOS transistors,
wherein the drain of said fourth NMOS transistor is connected to said first node, and
wherein the drain of said fourth PMOS transistor is connected to said second node.

6. The operational amplifier according to claim 1, further comprising:
a third constant current source supplying a current to said first node; and
a fourth constant current source supplying a current drawing a current from said second node.

7. The operational amplifier according to claim 5, further comprising: a floating current source connected between the drain of said third NMOS transistor and the drain of said PMOS transistor.

8. A display panel driver for driving a display panel, comprising:
an output circuit driving a data line of said display panel, said output circuit including an operational amplifier comprising:
a high-side output transistor connected between an output terminal connected to said data line and a positive power supply line;
a low-side output transistor connected between said output terminal and a negative power supply line;
a first capacitor element connected between a first node and said output terminal;
a second capacitor element connected between a second node and said output terminal;
a first PMOS transistor having a source connected to a gate of said high-side output transistor and a drain connected to a gate of said low-side output transistor;
a first NMOS transistor having a source connected to the gate of said low-side output transistor and a drain connected to the gate of said high-side output transistor;
a second PMOS transistor having a source connected to said first node and a drain connected to the gate of said high-side output transistor; and
a second NMOS transistor having a source connected to said second node and a drain connected to the gate of said low-side output transistor,
wherein gates of said first and second PMOS transistors are commonly connected and fed with a first bias voltage, and
wherein gates of said first and second NMOS transistors are commonly connected and fed with a second bias voltage.

9. A display device, comprising:
a display panel; and
a driver including an output circuit driving a data line of said display panel,
wherein said output circuit includes an operational amplifier comprising:
a high-side output transistor connected between an output terminal connected to said data line and a positive power supply line;
a low-side output transistor connected between said output terminal and a negative power supply line;
a first capacitor element connected between a first node and said output terminal;
a second capacitor element connected between a second node and said output terminal;
a first PMOS transistor having a source connected to a gate of said high-side output transistor and a drain connected to a gate of said low-side output transistor;
a first NMOS transistor having a source connected to the gate of said low-side output transistor and a drain connected to the gate of said high-side output transistor;
a second PMOS transistor having a source connected to said first node and a drain connected to the gate of said high-side output transistor; and
a second NMOS transistor having a source connected to said second node and a drain connected to the gate of said low-side output transistor,
wherein gates of said first and second PMOS transistors are commonly connected and fed with a first bias voltage, and
wherein gates of said first and second NMOS transistors are commonly connected and fed with a second bias voltage.
